(19) United States
(12) Patent Application Publication
(10) Pub. No.: US 2025/0174429 A1
(43) Pub. Date: May 29, 2025

(54) METHOD AND DEVICE FOR CORRECTING IMAGE ERRORS WHEN SCANNING A CHARGED PARTICLE BEAM OVER A SAMPLE

(71) Applicant: Carl Zeiss SMT GmbH, Oberkochen (DE)

(72) Inventor: Michael Budach, Hanau (DE)

(21) Appl. No.: 19/039,166

(22) Filed: Jan. 28, 2025

Related U.S. Application Data
(63) Continuation of application No. PCT/EP2023/071051, filed on Jul. 28, 2023.

(30) Foreign Application Priority Data
Aug. 1, 2022 (DE) 102022207930.2

(51) Int. Cl. H01J 37/22; H01J 37/147

(52) U.S. Cl. CPC H01J 37/222; H01J 37/147; H01J 2237/221

(57) ABSTRACT

The present application relates to a method and a device for correcting at least one image error when scanning a charged particle beam of a scanning particle microscope over a sample, the method comprising the steps of: (a) dividing a scanned region of the charged particle beam into at least two partial regions, with each of the at least two partial regions containing at least one structure element; (b) determining a correction value for the at least one structure element with regards to a target position of the at least one structure element for each of the at least two partial regions; and (c) correcting a beam deflection of the charged particle beam for at least one of the at least two partial regions using the determined correction value.

### CROSS-REFERENCE TO RELATED APPLICATIONS

The present patent application is continuation of and claims benefit under 35 U.S.C. § 120 from PCT application PCT/EP2023/071051, filed on Jul. 28, 2023, which claims priority from German patent application DE 10 2022 207 930.2, entitled “Verfahren und Vorrichtung zum Korrigieren von Abbildungsfehlern beim Rastern eines geladenen Teilchenstrahls über eine Probe,” which was filed with the German Patent and Trademark Office on Aug. 1, 2022. The entire contents of each of these earlier applications are incorporated herein by reference.

### TECHNICAL FIELD

The present invention relates to a method and a device for correcting image errors when scanning a charged particle beam over a sample, especially when scanning an electron beam over a photolithographic mask. The present invention also relates to the correction of at least one image error already when scanning the charged particle beam over the sample.

### BACKGROUND

Advances in nanotechnology make it possible to produce components with structure elements becoming smaller and smaller. The display and processing of the chip structures of microscopic or nanoscopic components requires tools which are able to image and modify these chip structures.

Microscopes are potent tools for imaging nanostructures. In microscopes, a particle beam typically interacts with a sample to be analyzed and/or processed. Microscopes that use particles with mass, for example electrons, to scan a sample have a high diffraction-limited resolution when imaging a nanostructure by way of scanning the particle beam over the sample, on account of the short de Broglie wavelength of the particles in the particle beam thereof. By way of example, electron beams can currently be focused on diameters in the single-digit nanometer range. Additionally, microscopes may contain tools that allow a sample to be processed. Processing may comprise mechanical and/or chemical processing.

In the case of electrically nonconductive samples or samples with poor electrical conductivity, which typically comprise a quartz substrate, for instance a photolithographic mask, the surface of the sample may become electrically charged when images are recorded using a charged particle beam. Electrical charging of a sample is problematic. By way of example, an electron beam creates falsifications, so-called scan artefacts, when scanning, which is to say imaging the sample, the said scan artefacts possibly significantly disturbing an image impression and, in particular, algorithmic image processing. This may even result in decisive details not even being reproduced in a recorded image.

U.S. Pat. No. 6,066,849 describes multiple scanning over a sample by way of an electron beam of a scanning electron microscope under different operating conditions, in order to compensate for sample charging while the sample is being imaged using the electron beam.

A sample is usually scanned in two dimensions by virtue of the charged particle beam of a particle beam microscope being guided over the sample line-by-line. The various lines are typically scanned successively in the horizontal direction. In the case of samples with rectilinear structures, for instance photolithographic masks, the imaging quality of the pattern elements depends on the alignment thereof with respect to the scanning direction or the line direction of the scan. This is illustrated schematically in the diagram 100 of FIG. 1. The exemplary sample 110 in FIG. 1 has a regular arrangement of squares 130 with edges 140. As symbolized by the arrows 190, the particle beam is scanned over the squares 130 or over the pattern elements 130 in the horizontal direction in the example illustrated. The edges 160 of a pattern element 130 of the sample 110 are imaged with significantly less contrast in the line direction 120 than the edges 150 of structure or pattern elements 130 which extend perpendicular to the scanning direction 120 of the particle beam. Moreover, strip-shaped artefacts 170 with a reduced intensity occur in the scanning direction 120; these appear darker in the diagram 100 than the remaining regions of the sample surface.

These difficulties are typically circumvented by virtue of a sample 110 being scanned diagonally with respect to its pattern elements 130. The scan artefacts still present in that case can be further reduced by virtue of a sample 110 being scanned multiple times in different directions. FIG. 2 shows the image 200 of an excerpt of the sample 110 of FIG. 1, obtained by the overlay of the data from two scans. The first scan 220 was carried out at an angle of 45° with respect to the horizontal and the second scan 230 was carried out at an angle of 135° with respect to the horizontal. This is symbolized by the arrows 290 in FIG. 2. The image 200 of the sample 110 reproduced in FIG. 2 is the result of the overlay of the data or image data from a first 220 and a second scan 230. Both the edges 250 of the structure elements 130 in the vertical direction and the edges 260 in the horizontal direction are delimited quite visibly and clearly. This means that although the scan artefacts 270 are still present, they could be significantly reduced by scanning 220, 230 the sample 110 two times in different directions 290.

So that the scan data or the images created from the data of the first 220 and the second scan 230 can be overlaid, the pixels of the two scans 220, 230 or scanning procedures 220, 230 must correspond to one another. This means that a pixel of the first scan 220 which is overlaid by a pixel of a second scan 230 must correspond to the same position on the sample 110. This assumes that the images of the first 220 and the second scan 230 are not offset and/or distorted with respect to one another.

This requirement places high demands on the reproducibility with which a charged particle beam can be scanned over a sample, which is to say on the linearity of the deflection functions x(t)=a·t and y(t)=b·t in the case of a line-by-line horizontal scan.

Electrostatic deflection systems for scanning a sample 110 by scanning 120, 220, 230 a charged particle beam usually have the demanded linearity on account of their high bandwidth. Moreover, electrostatic deflection systems generally do not exhibit any hysteresis.

Magnetic deflection systems can be used as an alternative to electrostatic deflection systems for the purpose of scanning 120, 220, 230 a charged particle beam over a sample 110. By contrast, magnetic deflection systems generally have a lower bandwidth than their electrostatic equivalents. Additionally, magnetic deflection systems exhibit a hysteresis. Moreover, eddy currents induced in metallic components in the vicinity of a magnetic deflection system can lead to a hardly controllable beam deflection component of a charged particle beam.

The combination of these effects can lead to the linearity of the deflection functions x_{M}(t) and y_{M}(t) of magnetic deflection systems being reduced vis-à-vis the electrostatic deflection systems. A consequence of this is that the pixels of different scanning procedures 220, 230 do not scan exactly the same position of the sample 110. As a result, image errors, for instance distortions which are manifested in ghost images or double images, may arise when the images of two scanning procedures 220, 230 of a sample 110 are overlaid. This is illustrated by the image 300 in FIG. 3, where data of two scans 220, 230 are combined. The left partial image 305 shows an image of a sample 310 with an arrangement of 81 squares 350 as an example for a structure element 350 which arises by overlaying two images or the data of two scanning procedures 220 and 230 of the sample 310—as illustrated by arrows 220 and 230 in FIG. 2.

The right partial image 395 reproduces the detail 330 of the sample 310 in enlarged fashion. It is clear from the enlarged illustration that the reproduction 360 of the structure element 350 of the first scan 220 is not congruent in the overlaid image 300 with the reproduction 380 of the structure element 350 of the second scan 230. Instead, an unsatisfactory linearity of the individual scanning procedures 220, 230 leads to image errors of the structure element 350 in the form of distortions in the individual reproductions 360, 380 of the structure element 350 of the different scans 220, 230, with the result that the reproductions 360, 380 or representations 360, 380 of the structure element 350 cannot be correctly overlaid from the data of the various scans 220, 230.

The present invention therefore addresses the problem of specifying a method and a device which allow the imaging of a sample with a charged particle beam of a scanning particle microscope to be improved.

### SUMMARY

According to an exemplary embodiment of the present invention, this problem is solved at least in part by means of the subjects of the independent claims 1 and 17 of the present application. Exemplary embodiments are described in the dependent claims.

In an embodiment, a method for correcting at least one image error when scanning a charged particle beam of a scanning particle microscope over a sample comprises the steps of: (a) dividing a scanned region of the charged particle beam into at least two partial regions, with each of the at least two partial regions containing at least one structure element; (b) determining a correction value of the at least one structure element with regards to a target position of the at least one structure element for each of the at least two partial regions; and (c) correcting a beam deflection of the charged particle beam for at least one of the at least two partial regions using the determined correction value.

As discussed above, unsatisfactory linearity of a deflection system which scans a charged particle beam over a sample may lead to one or more positioning errors of the charged particle beam compared to the intended positions of the charged particle beam on the sample. Positioning errors of a charged particle beam caused by a non-perfect linearity of a deflection system may result in an image error in form of distortions, e.g., when representing the recorded data as an image on a monitor. Typically, an ideal image of the sample is not available. Hence, a small distortion cannot be detected in a single recorded image.

However, when scanning a sample using a deflection system having nonlinear deflection functions, e.g., causing positioning errors of the charged particle beam, under different directions and overlaying or superimposing the different scans, the distortions of the individual representations can result in image errors in form of ghost images or double images. Thus, positioning errors, e.g. of a scanning charged particle beam, can cause image errors when representing the recorded data on a monitor.

After carrying out a calibration process, a method according to the invention allows the correction of a nonlinear deflection of the charged particle beam by virtue of at least one of the at least two partial regions being corrected by use of a time-dependent and/or position-dependent correction value. Preferably, all of the at least two partial regions are corrected with the aid of time-dependent and/or position-dependent correction values. The linearization of the beam deflection of the charged particle beam thereby causes image errors, for example distortions, to be largely avoided when imaging a sample. Computationally intensive postprocessing of a recorded image of a sample can be dispensed with.

In particular, a method according to the invention can be advantageously used whenever an image of a sample is created from data generated by use of two or more scanning procedures.

A sample may have a specific calibration structure for the purpose of carrying out a calibration process. The structure element or elements of a calibration structure may be adapted to the intended purpose. It is advantageous if the structure element or elements of the calibration structure extend over a majority of the scanned region of the charged particle beam. Ideally, the structure element or elements of the calibration structure cover the scanned region uniformly and completely. Preferably, a calibration structure is arranged on a part of a sample that is not required by the latter to fulfil its function. By way of example, a calibration structure may be arranged on a non-active region of a photolithographic mask.

However, alternatively and/or in addition, a calibration process can also be carried out on a part of a sample which has a suitable number of preferably rectilinear structure elements.

By choosing the size of the scanned region, which is to say the magnification, with which the charged particle beam scans a sample, it is possible to set, in addition to the granularity of the partial regions, the precision with which a non-linear deflection of a charged particle beam can be corrected. Typically, the size of the scanned region (field of view, FOV) is specified by the application. Therefore, it may be advantageous to use a different or dedicated calibration for each size of the scanned region. Further, it is advantageous to adapt the calibration structure used to this end to the size of the scanned region. The larger the FOV or scanned region, the stronger the electric or magnetic fields have to be to deflect the charged particle beam. However, all effects that are detrimental to the linearity of the beam deflection appear more strongly as a result. A correction or linearization of the beam deflection is particularly important for large scanned regions of a charged particle beam of a scanning particle microscope.

Alternatively, a specifically designed calibration element with one or more calibration structures can be used to carry out a calibration process. The calibration element may comprise calibration structures whose structure elements are adapted to different settings of the scanning particle microscope, for example to the size of the scanned region and/or the magnification of the scanning particle microscope.

After carrying out a calibration process, either on the basis of a separate calibration element or on the basis of a calibration structure present on a sample, the determined correction values can be used to linearize the deflection of a charged particle beam when examining a number of samples. Consequently, only one sample from a set of identical or similar samples requires a calibration structure.

The calibration process can be repeated following a change in the settings of the scanning particle microscope. Further, it is possible to repeat the calibration process at regular or irregular time intervals during the operation of the scanning particle microscope. This means that correction values, determined once, can be used to correct scanning procedures or images, determined therefrom, of various samples.

The method according to the invention is preferably used to correct or linearize magnetic deflection systems of a charged particle beam. However, the defined method also enables an improvement in the linearity of electrostatic deflection systems, especially if their bandwidth is limited.

Samples whose regions to be examined have lateral dimensions which exceed the maximum scanned region of a charged particle beam of a scanning particle microscope or which are scanned at a high resolution and whose FOV only has a small area can be scanned using the charged particle beam by virtue of the sample being divided into a plurality of scanned regions, generally N scanned regions, which are successively scanned by the charged particle beam by way of an appropriate displacement of the sample. To linearize the deflection of the charged particle beam when scanning each individual partial region of the sample to be analyzed, use can be made of the correction values for each scanned region of the sample to be examined, which were determined with the aid of a calibration structure within a calibration process.

The division of the scanned region into the at least two partial regions can be implemented in automated fashion on the basis of algorithmic image processing. As a result, a method according to the invention requires no human interaction.

The at least two partial regions may comprise 2ⁿ partial regions with n≥2. The number of partial regions into which the scanned region is divided defines the number of correction values which are determined within the scanned region of a charged particle beam. As a result, this defines the number of time-discrete correction values which are used to correct the time-continuous deflection signal of the charged particle beam.

The sample may comprise any type of photolithographic mask. A photolithographic mask typically has rectangular structure elements. The charged particle beam may comprise an electron beam and/or an ion beam.

The at least one structure element may comprise a topographic change of the sample and/or a change of a material composition of the sample.

It is advantageous if the at least one structure element has a topographic change for the purpose of creating a topographic contrast and a change of a material composition for the purpose of creating a material contrast in an image recorded by the charged particle beam.

The at least one structure element of the first partial region of the scanned region may be identical to the at least one second structure element of the at least one second partial region. However, the structure element of the first partial region may also differ from the structure element of the at least one second partial region of the scanned region.

The determination of the correction value may comprise: first scanning of the charged particle beam over the at least two partial regions in a first line direction with regards to the at least one structure element, and at least one second scanning of the charged particle beam over the at least two partial regions in at least one second line direction, the at least one second line direction having an angle with respect to the first line direction that differs from 0°.

It may be advantageous to determine correction values from two or more scanning procedures and to use these correction values when recording an image of the sample from data of a single scanning process.

The at least one structure element may have a rectilinear structure, and the first line direction may have an angle of 45° with respect to the at least one structure element.

The diagonal scanning of a rectilinear structure element of a sample leads to a significantly lesser appearance of scan artefacts in comparison with a scan of a rectangular or rectilinear structure element parallel to one of the sides of the rectangle or rectilinear structure element.

Determining the correction value may further comprise: creating an overlaid image from the data from the first scan and from the at least one second scan.

By virtue of a sample with at least one structure element being scanned in two different directions and the obtained data being displayed in an image, it is possible in the overlaid image to make the distortions caused by a not perfectly linear deflection of the charged particle beam visible. The image errors can be quantified by an appropriate analysis of the various reproductions or representations of a structure element in an overlaid image. The deflection function over the various partial regions of a scanned region of the charged particle beam can be linearized by determining correction values for different partial regions of a scanned region.

Determining the target position may further comprise: forming a mean value of a first reproduction of the at least one structure element and at least one second reproduction of the at least one structure element in the overlaid image, and the mean value can determine the target position of the at least one structure element.

Determining the correction value may comprise: determining a first deviation from the target position and determining at least one second deviation from the target position.

Determining a first deviation from the target position and determining at least one second deviation from the target position may comprise: determining a difference between the target position of the at least one structure element and a first reproduction of the at least one structure element in the overlaid image, and determining the at least one second deviation from the target position may comprise: determining a difference between the target position of the at least one structure element and the at least one second reproduction of the at least one structure element in the overlaid image.

The first deviation may comprise a first correction value which is used when carrying out the first scanning process. The at least one second deviation may comprise at least one second correction value which is used when carrying out the at least one second scanning process. The first deviation and the at least one second deviation may comprise two-dimensional vectors in the sample plane.

Determining the correction value may comprise: forming a mean value from an absolute value of the first and an absolute value of the at least one second deviation for determining the correction value.

For the case of determining two correction values, it is possible to determine two correction values whose absolute values for the two directions are identical rather than correction values in the form of two vectors with different lengths or different absolute values.

The mean value may comprise at least one element from the group of: an arithmetic mean, a geometric mean, a harmonic mean, a weighted arithmetic mean, a weighted geometric mean, and a weighted harmonic mean.

The second line direction may include an angle of 90° with respect to the first line direction.

First scanning of a rectangular structure element at 45° with respect to one of the sides of the structure element and second scanning, within the scope of which the line direction has been rotated through 90° with respect to the line direction of the first scanning, is preferable since this minimizes the scan artefacts, while still having a limited outlay for a pictorial representation of the structure element.

The at least one second scanning may comprise two scanning procedures and the two second line directions may include angles of 60° and 120° with the first line direction, or the at least one second scanning may comprise three scanning procedures and the three second line directions may include angles of 45°, 90° and 135° with the first line direction.

Determining the correction value may comprise: determining the correction value from scan parameters on the basis of a dynamic model. A dynamic model describes the system behaviour of the scanning particle microscope in the form of a mathematical function. By way of example, the latter may have the following form:

$$( \begin{matrix}{x}_{k} \\ {y}_{k}\end{matrix} ) = f ( x , y , \dot{x} , \dot{y} , \ddot{x} , \ddot{y} , {x}^{...} , {y}^{...} )$$

where xₖ and yₖ are the sought-after correction values.

The method further may include the step of: interpolating between the correction values of adjacent partial regions and/or extrapolating the correction value into a partial region, if the latter delimits one side of the scanned region of the charged particle beam. The interpolation may comprise a linear interpolation and the extrapolation may comprise a linear extrapolation.

By way of an interpolation and extrapolation of the position-discrete and hence time-discrete correction values, it is possible to determine a time-continuous correction function for a scanned region of the charged particle beam, by means of which the deflection signal of the charged particle beam is corrected or linearized.

The correction of the beam deflection of the charged particle beam using the determined correction value can be implemented when scanning a partial region of the scanned region and/or when reproducing an image of the scanned partial region of the scanned region.

The correction of a non-linear deflection of the charged particle beam can be implemented already within the scope of scanning a sample by virtue of the correction values for the currently scanned partial region of the scanned region of the sample being added to the deflection signal of the charged particle beam. As a result, the data recorded by the scanning have substantially no linearity errors. However, when representing or reproducing the data on a visual display unit, the measurement data determined on the basis of the scanning procedures can also be corrected by use of the correction values determined for the respective partial regions of the scanned region.

A computer program can comprise instructions that cause a computer system to carry out the method steps of the aspects described herein when the computer program is executed by the computer system.

In an embodiment, a device for correcting at least one image error when scanning a charged particle beam of a scanning particle microscope over a sample has: (a) means for dividing a scanned region of the charged particle beam into at least two partial regions, with each of the at least two partial regions containing at least one structure element; (b) means for determining a correction value for the at least one structure element with regards to a target position of the at least one structure element for each of the at least two partial regions; and (c) means for correcting a beam deflection of the charged particle beam for at least one of the at least two partial regions using the determined correction value.

The device can be configured to carry out the method steps described herein.

The means for determining the correction values may comprise a magnetic deflection system and/or an electrostatic deflection system for scanning the charged particle beam over the sample.

The means for dividing the scanned region into at least two partial regions and/or for correcting the beam deflection for at least one of the at least two partial regions or for each of the at least two partial regions of the scanned region may comprise an image processing program.

The means for correcting the beam deflection of the charged particle beam may comprise a computer system. The computer system may comprise a non-volatile memory for storing the image processing program.

A method according to the invention allows the correction of an insufficient linearity of preferably a magnetic deflection system when scanning the charged particle beam over a sample. As a result, the disadvantages of a magnetic deflection system vis-à-vis an electrostatic deflection system can be largely compensated for.

Further, the device may have at least one means for processing the sample. The at least one processing means may comprise a micromanipulator for processing a sample, in particular for removing a particle and/or a defect from the sample.

### BRIEF DESCRIPTION OF DRAWINGS

The detailed description that follows describes currently preferred exemplary embodiments of the invention with reference to the drawings, wherein:

FIG. 1 shows an image of a detail of a sample with square pattern elements according to the prior art, the image being recorded by horizontal scanning of an electron beam over the sample;

FIG. 2 reproduces the image of the detail of FIG. 1 according to the prior art, wherein the image is generated by the overlay of the data from two diagonal scans of the sample, as symbolized by arrows;

FIG. 3 illustrates the reproduction of 81 structure elements according to the prior art in the left partial image, generated by two implementations of diagonal scanning of the structure elements, and reproduces an enlarged detail of the left partial image in the right partial image;

FIG. 4 reproduces the left partial image of FIG. 3 which serves as an exemplary calibration structure, on the basis of which the calibration process described in this application is explained;

FIG. 5 illustrates the correction values determined for the different partial regions of the scanned region in FIG. 4, in relation to a target position of two scanning procedures for the scanning directions of FIG. 2;

FIG. 6 presents the x-component of the deflection function of a charged particle beam as a function of time on the right-hand ordinate and reproduces the associated absolute value of the correction value as a function of time on the left-hand ordinate;

FIG. 7 shows an image of the calibration structure of FIG. 4, which was generated by overlaying the data from two diagonal scans, wherein the deflection signal of the charged particle beam, as illustrated in FIG. 6, was corrected; and

FIG. 8 represents a flowchart of a method for correcting at least one image error when scanning a charged particle beam over a sample.

### DETAILED DESCRIPTION

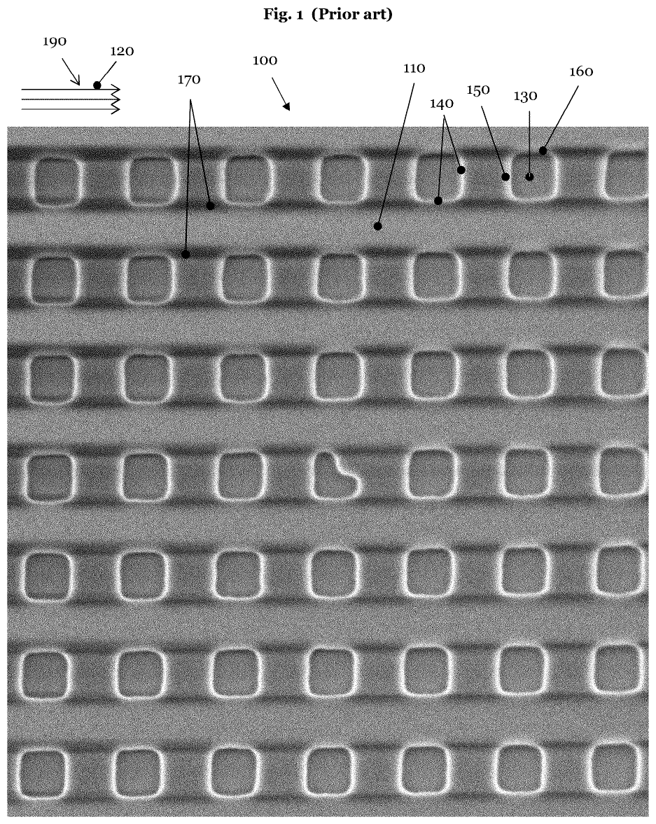

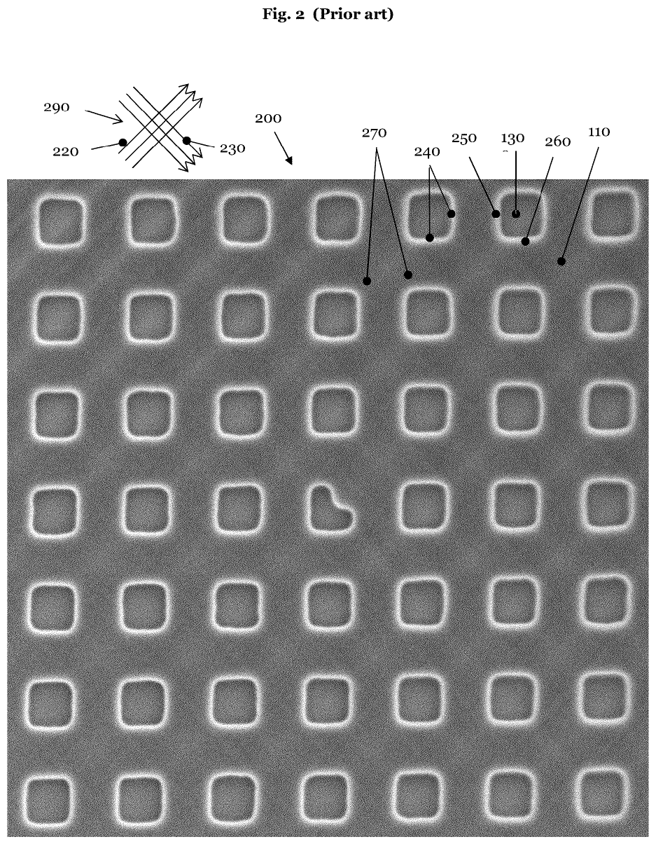

Currently preferred embodiments of devices and methods according to the invention are explained hereinbelow. These are explained in detail using the example of a scanning electron microscope (SEM). However, devices and methods according to the invention are not restricted to the use of a beam of particles with mass, in the form of an electron beam. Rather, these can be used for any particle beams which use particles in the form of bosons or fermions if the particle beams are scanned over a sample for the purposes of imaging the latter. Further, the use of devices and methods according to the invention is explained using the example of a photolithographic mask. However, this likewise does not represent any restriction. Rather, devices and methods according to the invention can be used for imaging and processing any desired sample. By way of example, the methods and devices described in this application can be used to image and modify chip structures or semiconductor structures on wafers, MEMS (micro-electromechanical systems), NEMS (nano-electromechanical systems) and/or PICs (photonic integrated circuits) by use of a particle beam or by use of a mechanical processing process. FIGS. 1 to 3 which explain the prior art have already been discussed hereinabove.

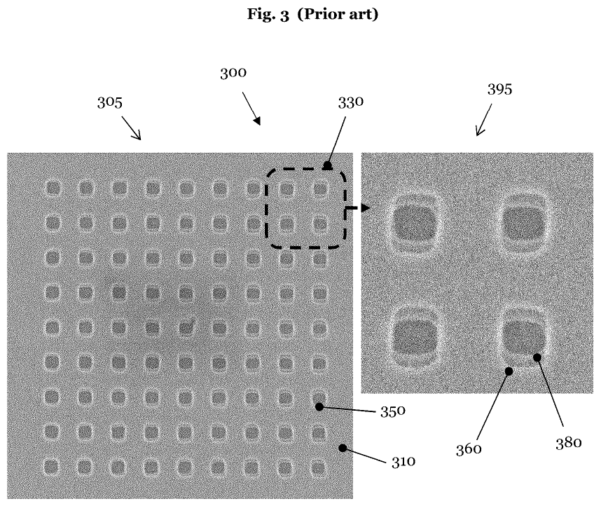

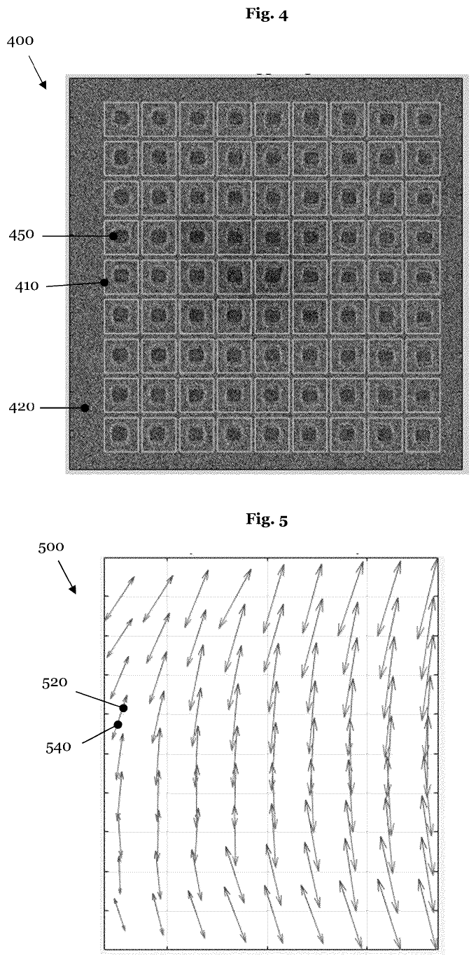

FIG. 4 once again reproduces the detail of the sample 310 of the left partial image 305 of FIG. 3. The detail of the sample 310 represents an exemplary calibration structure 400. In the example described, the calibration structure 400 is a part or detail of a sample 310 to be examined, for example a photolithographic mask. By way of example, the calibration structure 400 may be arranged outside of an active region of the photolithographic mask. However, it is also possible to carry out a calibration process for determining correction values for a deflection signal of a charged particle beam on pattern elements of a photolithographic mask. Moreover, a calibration element which was designed specifically to this end and which has a plurality of calibration structures adapted to various settings of a scanning particle microscope can be used to carry out a calibration process.

The calibration structure 400 serves to carry out a calibration process for the purpose of determining correction values, which are preferably used to improve the linearity when scanning the charged electron beam for the parts of the sample 310 to be examined.

It is self-evidently also possible for the calibration structure 400 to not be part of a sample to be analyzed but to be designed as an independent calibration element having one or more calibration structures, which are adapted to the scanned region of the electron beam and/or to the settings of the scanning electron microscope.

A calibration structure 400 comprises a scanned region 420 of a charged particle beam of a scanning electron microscope as an example of a scanning particle microscope. In the example illustrated in FIG. 4, the calibration structure 400 comprises 81 structure elements 450.

In a first step for determining correction values for the deflection signal for scanning the charged particle beam over the scanned region 420 of the calibration structure 400, the latter is divided into partial regions 410. Two partial regions 410 are the minimum number of partial regions 410 into which the scanned region 420 is divided. The maximum number of partial regions 410 is defined by the number of pixels with which the data of a scanning procedure are depicted on a monitor. The size of the partial regions 410 determines the granularity with which correction values are determined within the scanned region 420. The greater the number of partial regions 410, the more correction values are determined for the scanned region 420 of the charged particle beam and the better the deflection of the charged particle beam can be corrected, which is to say linearized, with the aid of the determined correction values. This advantage is paid for by an increased computational outlay for determining the correction values.

Software, for instance in the form of an image processing program, can be used to divide a scanned region 420 of the charged particle beam into partial regions 410.

The exemplary calibration structure 400 in FIG. 4 has structure elements 450 in the form of squares in a square arrangement. This means that each partial region 410 of the scanned region 420 has one structure element 450 in the example illustrated in FIG. 4. As already explained in the context of FIG. 3, the data of two scans 220, 230 or two scanning procedures are combined or overlaid in the image 300. The first scanning process 220 scans the partial regions 410 or the structure elements 350 at an angle of 45° with respect to the horizontal. During the second scanning 230, the line direction has an angle of 135° vis-à-vis the horizontal direction or an angle of 90° with respect to the line direction of the first scanning 220.

As illustrated in the context of FIG. 3, the structure element 350 is not correctly overlaid during the first scanning 220 and the second scanning 230; instead, the structure element 350 is reproduced once as square 360 and once as square 380 in the overlaid image 395.

After scanning the calibration structure 400 twice—as described in the context of FIG. 3—a target position of the structure element 450 of each partial region 410 of the scanned region 420 can be determined in the overlaid image, which is to say in the image in which the data of the scans 220 and 230 are reproduced, by way of forming the mean value of the positions of the structure element 450 of the calibration structure 400.

In the next step for determining the correction values, a first deviation 520 of the structure element 450 from a target position of the structure element 450 is determined. This first deviation 520 of the structure element 450 from the target position of the structure element 450 is symbolized by the arrows 520 in FIG. 5. The arrow 520 presents the shift of the structure element 450 of the calibration structure 400 which was produced by the first scan 220. Further, a second deviation 540 of the structure element 450 from the target position of the structure element 450 is determined by subtraction for each partial region 410 of the scanned region 420. The second deviation 540 is reproduced by arrows 540 in FIG. 5. The first 520 and the second deviation 540 are two-dimensional (2-D) vectors in the sample plane or in the plane of the calibration structure 400 and provide correction values for respectively one partial region 410 of the scanned region 420. In the case of two scans 220, 230 carried out at an angle of 90°, the absolute value and hence length of the 2-D vectors 520, 540 is equal, but they point in opposite directions.

When scanning a partial region 410 of the scanned region 420 of the sample 310 to be examined, the first 520 and the second deviation 540 can be used to correct the beam position of the charged particle beam during a scan of the partial region 410 of the scanned region 420.

The first 520 and the second deviation 540 are partial region-specific correction values which have constant values within a partial region 410 of the scanned region 420. The absolute value of the deviation can be determined from the two deviations 520 and 540, or from three or more deviations should the overlaid image contain three or more scans, by way of forming a mean value. The resultant deviations are in the form of two-dimensional vectors which, in the general case, have different lengths and point in different directions.

A time-continuous two-dimensional correction function can be determined from the discrete partial region-specific deviations 520 and 540 by way of an interpolation between the various partial regions 410. Should a partial region 410 be located at the edge of the scanned region 420, then the correction function can be extrapolated to the edge of the scanned region 420. Typically, a linear interpolation and extrapolation over the scanned region 420 of the charged particle beam supplies a good linearization of the scanning of a sample 310 by a charged particle beam. However, if necessary, it is also possible to use higher-degree polynomials for the interpolation or extrapolation of the partial region-specific deviations 520 and 540.

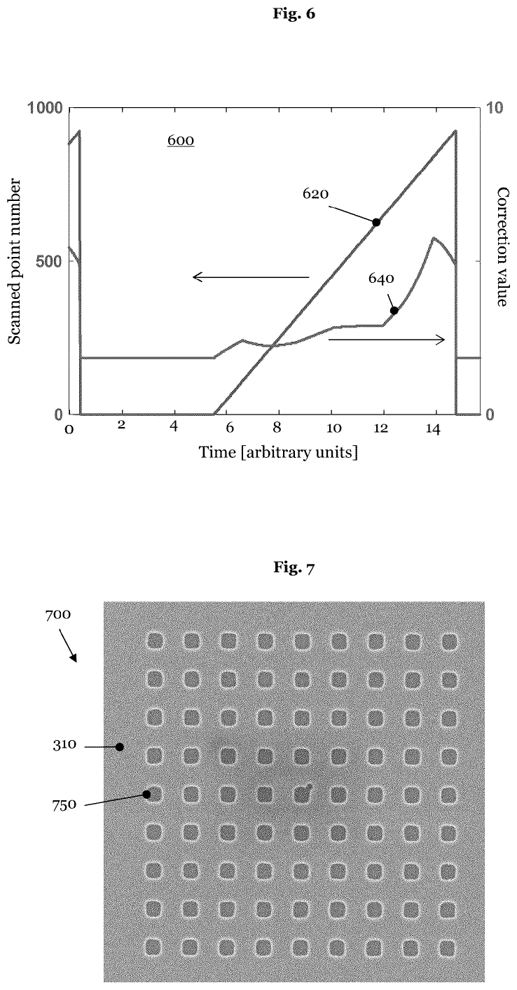

The diagram 600 in FIG. 6 shows, with reference to the left-hand ordinate, the x-component of a deflection signal 620 as function of time in exemplary fashion and, additionally, the associated correction signal 640 with reference to the right-hand ordinate. The x-component of the time-continuous correction signal 640 has numerical values of the order of one percent of the deflection signal 620.

Each point (x, y) of the scanned region 420 of the charged particle beam is assigned a correction vector (Δx, Δy) by way of the two-dimensional time-continuous function (Δx(t), Δy(t)). During each new scanning process of the sample 310, this correction value (Δx, Δy) is used to correct, which is to say make available, the beam position of the charged particle beam by the correction vector (Δx, Δy). This makes it possible to prevent image errors from arising; instead, the creation thereof can already be avoided when scanning the sample 310.

Alternatively and/or in addition, it is naturally also possible to store the data, generated by scanning the charged particle beam over the structure elements 350 of the sample 310, together with the associated correction values 520, 540, which were determined by a calibration process with the aid of calibration structure 400. When displaying or reproducing the data or image data on a monitor, these can then be corrected on the basis of the associated correction values 520, 540.

FIG. 7 once again shows the detail of the sample 310 of the left partial image 305 of FIG. 3. However, in the case of the two scans 220 and 230 for recording the data, the beam deflection of the charged particle beam was corrected during the scanning, as described hereinabove. The data 360 and 380 recorded by the two scans 220, 230 can be overlaid correctly, which is to say without offset or distortion, as illustrated by the reference sign 750. Image errors caused by scan artefacts such as the double images depicted in FIG. 3 no longer occur.

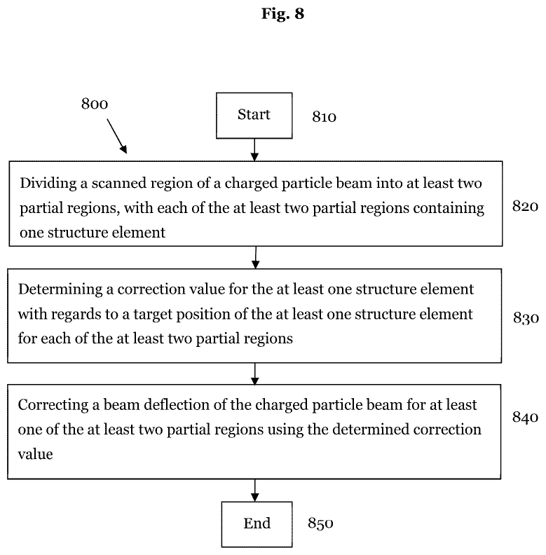

Finally, FIG. 8 presents a flowchart 800 which reproduces a few essential steps of the method according to the invention for correcting image errors when scanning a charged particle beam of a scanning particle microscope over a sample 310. The method begins in step 810. A scanned region 420 is divided into at least two partial regions 410 in a first step 820, with each partial region 410 comprising at least one structure element 450. Image processing software can be used to divide a scanned region 420 into two or more partial regions 410. It is advantageous if the structure element or elements 450 is/are arranged uniformly over the scanned region 420 of the charged particle beam.

In the next step 830, a correction value 520, 540 is determined for the at least one structure element 450 with regards to a target position of the at least one structure element 450 for each of the at least two partial regions 410. Determining a correction value 520, 540 comprises scanning the at least two partial regions 410 at least twice using a charged particle beam, with different line directions 220, 230. Determining the correction value 520, 540 from the data of the at least two scans 220, 230 can be carried out by use of a dedicated image processing program. For each partial region 410 of the scanned region 420, the correction value 520, 540 comprises a two-dimensional vector in the sample plane.

In an optional step, not depicted in the flowchart 800, a two-dimensional time-continuous correction function (Δx(t), Δy(t)) can be derived by interpolation and extrapolation between the various partial regions 410 of the scanned region 420 from the discrete correction value 520, 540 which is constant within a partial region 410.

Thereupon, a beam deflection of the charged particle beam is corrected in step 840 for at least one of the at least two partial regions 410 of the scanned region 420 using the determined correction value 520, 540. Preferably, the beam deflection for each of the at least two partial regions 410 of the scanned region 420 is corrected using the determined correction value 520, 540. This correction can be implemented in two different ways. Firstly, the correction values 520, 540 can already be used during the scanning of the charged particle beam over the sample 310, in order to linearize the beam deflection. Secondly, the determined correction values 520, 540 can be used to correct deviations from the linearity of the beam deflection during a representation or reproduction of the data, generated by the scans 220, 230, as an image.

Finally, the method ends in step 850.

What is claimed is:

1. A method for correcting at least one positioning error caused by a magnetic deflection system when scanning a charged particle beam of a scanning particle microscope over a sample, the method comprising:
a. dividing a scanned region of the charged particle beam into at least two partial regions, with each of the at least two partial regions containing at least one structure element;
b. determining a correction value for the at least one structure element with regards to a target position of the at least one structure element for each of the at least two partial regions; and
c. correcting a beam deflection of the charged particle beam caused by the magnetic deflection system for at least one of the at least two partial regions using the determined correction value.

2. The method according to claim 1, wherein the division of the scanned region into the at least two partial regions is implemented in automated fashion on the basis of algorithmic image processing.

3. The method according to claim 1, wherein the at least two partial regions comprise 2ⁿ partial regions with n≥2.

4. The method according to claim 1, wherein the at least one structure element comprises at least one of a topographic change of the sample or a change of the material composition of the sample.

5. The method according to claim 1, wherein the determination of the correction value comprises: first scanning of the charged particle beam over the at least two partial regions in a first line direction with regards to the at least one structure element, and at least one second scanning of the charged particle beam over the at least two partial regions in at least one second line direction, the at least one second line direction having an angle with respect to the first line direction that differs from 0°.

6. The method according to claim 1, wherein the at least one structure element has a rectilinear structure, and the first line direction has an angle of 45° with respect to the at least one structure element.

7. The method according to claim 5, wherein the determination of the correction value further comprises: creating an overlaid image from data from the first scan and data from the at least one second scan.

8. The method according to claim 1, wherein the determination of the target position comprises: forming a mean value of a first reproduction of the at least one structure element and at least one second reproduction of the at least one structure element in the overlaid image, with the mean value determining the target position of the at least one structure element.

9. The method according to claim 8, wherein the determination of the correction value comprises: determining a first deviation from the target position and determining at least one second deviation from the target position.

10. The method according to claim 9, wherein the determination of a first deviation from the target position and the determination of the at least one second deviation from the target position comprises: determining a difference between the target position of the at least one structure element and a first reproduction of the at least one structure element in the overlaid image, and wherein the determination of the at least one second deviation from the target position comprises: determining a difference between the target position of the at least one structure element and at least one second reproduction of the at least one structure element in the overlaid image.

11. The method according to claim 10, wherein the first deviation comprises a first correction value for performing the first scanning using the magnetic deflection system, and wherein the at least one second deviation comprises at least one second correction value for performing the at least one second scanning using the magnetic deflection system.

12. The method according to claim 10, wherein the determination of the correction value comprises: forming a mean value from an absolute value of the first and the at least one second deviation for determining the correction value.

13. The method according to claim 5, wherein the second line direction includes an angle of 90° with respect to the first line direction.

14. The method according to claim 1, further including at least one of: interpolating between the correction values of adjacent partial regions or extrapolating the correction value into a partial region, if the latter delimits one side of the scanned region of the charged particle beam.

15. The method according to claim 1, wherein the correction of the beam deflection of the charged particle beam using the determined correction value is implemented when at least one of scanning a partial region of the scanned region or reproducing an image of the scanned partial region of the scanned region.

16. A computer program comprising instructions that prompt a computer system to carry out the method steps of claim 1 when the computer program is executed by the computer system.

17. A device for correcting at least one positioning error caused by a magnetic deflection system when scanning a charged particle beam of a scanning particle microscope over a sample, having:
a. means for dividing a scanned region of the charged particle beam into at least two partial regions, with each of the at least two partial regions containing at least one structure element;
b. means for determining a correction value for the at least one structure element with regards to a target position of the at least one structure element for each of the at least two partial regions; and
c. means for correcting a beam deflection of the charged particle beam caused by the magnetic deflection system for at least one of the at least two partial regions using the determined correction value.

18. The device according to claim 17, wherein the device is configured to carry out a method for correcting the at least one positioning error caused by the magnetic deflection system when scanning the charged particle beam of the scanning particle microscope over the sample, the method comprising:
d. dividing a scanned region of the charged particle beam into at least two partial regions, with each of the at least two partial regions containing at least one structure element;
e. determining a correction value for the at least one structure element with regards to a target position of the at least one structure element for each of the at least two partial regions; and
f. correcting a beam deflection of the charged particle beam caused by the magnetic deflection system for at least one of the at least two partial regions using the determined correction value.

19. The device according to claim 17, further comprising means for processing the sample.

20. The device according to claim 17, wherein the means for at least one of dividing the scanned region into partial regions or correcting the beam deflection for the magnetic deflection system for each of the at least two partial regions comprises an image processing program.
